(19) United States
(12) Patent Application Publication
(10) Pub. No.: US 2016/0043260 A1
(43) Pub. Date: Feb. 11, 2016

(54) Solar Energy Conversion Apparatus, and Methods of Making and Using the Same

(71) Applicants: Robert J. Nemanich, Scottsdale, AZ (US); Franz A.M. Koeck, Tempe, AZ (US); Tianyin Sun, Tempe, AZ (US)

(72) Inventors: Robert J. Nemanich, Scottsdale, AZ (US); Franz A.M. Koeck, Tempe, AZ (US); Tianyin Sun, Tempe, AZ (US)

(21) Appl. No.: 14/823,132

(22) Filed: Aug. 11, 2015

Related U.S. Application Data
(60) Provisional application No. 62/035,706, filed on Aug. 11, 2014.

(51) Int. Cl. H01L 31/074; H01L 31/18; H01L 31/065

(52) U.S. Cl. CPC H01L 31/074; H01L 31/065; H01L 31/1804

(57) ABSTRACT

Apparatuses and methods are provided for converting solar energy. The apparatus can include an emitter electrode, a collector electrode, a vacuum gap, and an electronic circuit. The emitter electrode can include a first light absorbing layer in direct contact with a first low work function layer. The vacuum gap can be disposed between the emitter and the collector. The vacuum gap can be in direct contact with the first low function layer. The electronic circuit can be coupled to the emitter electrode and the collector electrode. The first low work function layer can be disposed at least partially between the first light absorbing layer and the vacuum gap.

### CROSS-REFERENCES TO RELATED APPLICATIONS

This application claims priority to U.S. Provisional Patent Application No. 62/035,706, filed Aug. 11, 2014, the entire contents of which are incorporated by reference herein.

### STATEMENT REGARDING FEDERALLY SPONSORED RESEARCH

This invention was made with government support under N00014-10-1-0540 awarded by the Office of Navel Research. The government has certain rights in the invention.

### BACKGROUND OF THE INVENTION

This disclosure relates to solar energy conversion.

Photons have been employed to generate electron emission from novel materials through various physical mechanisms. Notably, a new emission mechanism that combines photo- and thermal excitation, namely photon-enhanced thermionic emission (PETE), has been proposed to describe results for Cs-coated p-type GaN. Several theoretical studies have described possible application of PETE in concentrated solar-thermionic energy conversion devices. In a recent experimental study, photon-enhanced thermionic emission using a p-type GaAs/p-type AlGaAs hetero junction interface was explored, and the results indicated the spatial separation of photon absorption and electron emission in a PETE device. These prior results employed notably unstable cesiated surfaces to indicate the PETE effect, which calls for studies involving new methods to decrease the emission barrier.

Diamond films obtain a negative electron affinity (NEA) after hydrogen passivation where the electron affinity is defined as the energy required to remove an electron from the conduction band minimum (CBM) of a semiconductor into vacuum away from the surface. For NEA diamond films, conduction band electrons can be readily emitted without overcoming an energy barrier. For crystalline diamond, n-type doping has been achieved by incorporation of nitrogen or phosphorus, with a donor level of nitrogen at 1.7 eV and that of phosphorus at 0.6 eV below the CBM. The strong upward band bending often observed in n-type doped diamond can be mitigated in nanocrystalline diamond apparently because of the sp2 bonds at the grain boundaries. As a result, n-type doping of nanocrystalline diamond leads to lowering of the electron emission threshold, i.e. the effective work function Φ_{W}, which is defined for NEA materials to be the energy difference between the CBM and the Fermi level (E_{F}). Effective work functions of 1.3 eV with nitrogen-doping and 0.9 eV with phosphorus-doping have been reported for n-type CVD diamond. These low work function surfaces enable visible light photo-induced electron emission and low temperature thermionic electron emission from diamond films on metallic substrates.

### SUMMARY OF THE INVENTION

The present disclosure provides an apparatus including an emitter electrode, a collector electrode, a vacuum gap, and an electronic circuit. The emitter electrode can include a first light absorbing layer in direct contact with a first low work function layer. The vacuum gap can be disposed between the emitter and the collector. The vacuum gap can be in direct contact with the first low work function layer. The electronic circuit can be coupled to the emitter electrode and the collector electrode. The first low work function layer can be disposed at least partially between the first light absorbing layer and the vacuum gap.

The present disclosure also provides a heterostructure. The heterostructure can include a light absorbing layer and a low work function layer in direct contact with the light absorbing layer.

The present disclosure also provides a method of making an apparatus. The method can include one or more of the following steps: obtaining a trilayer structure comprising a first light absorbing layer, a spacer layer, and a sacrificial layer; selectively patterning a photoresist onto a surface of the sacrificial layer to provide a photoresist-patterned trilayer structure covered areas and uncovered areas; etching the photoresist-patterned trilayer structure to remove material beneath uncovered areas to provide an etched trilayer structure having etched portions beneath the uncovered areas, wherein etching removes the sacrificial layer and spacer layer from the etched portion and optionally removes a portion of the first light absorbing layer from the etched portion; removing the photoresist and depositing a first low work function layer onto the surface of the etched trilayer structure and/or into the etched portion of the etched trilayer structure to provide an etched tetralayer structure; selectively depositing a second sacrificial layer onto a bottom of the etched portions of the etched tetralayer structure to provide an etched pentalayer structure; etching the etched pentalayer structure to remove the second sacrificial layer and at least a portion of the first low work function layer that is not located at the bottom of the etched portions to provide a heterostructure or emitter electrode comprising a first light absorbing layer and a first low worth function, wherein the spacer layer is attached to the heterostructure or emitter electrode; obtaining a bilayer structure comprising a second light absorbing layer and a second low work function layer; contacting the second low work function layer to the spacer layer; and creating a vacuum gap between the first low work function layer and the second low work function layer.

It is therefore an advantage of the disclosure to provide a solar energy conversion apparatus with improved solar energy conversion properties.

These and other features, aspects, and advantages of the present disclosure will become better understood upon consideration of the following detailed description, drawings and appended claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a schematic of an isothermal photon-enhances thermionic emission converter cell, in accordance with the present disclosure.

FIG. 2 is a block diagram showing the steps of a method of making an apparatus, in accordance with the present disclosure.

FIG. 3A is a schematic of a portion of a method of making an apparatus, in accordance with the present disclosure.

FIG. 3B is a schematic of a portion of a method of making an apparatus, in accordance with the present disclosure.

FIG. 4 is a block diagram showing the steps of a method of converting solar energy, in accordance with the present disclosure.

FIG. 5A is a plot of the photon-enhanced emission spectra from nitrogen-doped diamond films on a p-type doped Si substrate at 400 nm, obtained by subtracting the thermionic emission contribution from the combined emission spectra, in accordance with the present disclosure. The corresponding photon energies are labeled with solid lines relative to E_{F}.

FIG. 5B is a plot of the photon-enhanced emission spectra from nitrogen-doped diamond films on a p-type doped Si substrate at 430 nm, obtained by subtracting the thermionic emission contribution from the combined emission spectra, in accordance with the present disclosure. The corresponding photon energies are labeled with solid lines relative to E_{F}.

FIG. 5C is a plot of the photon-enhanced emission spectra from nitrogen-doped diamond films on a p-type doped Si substrate at 450 nm, obtained by subtracting the thermionic emission contribution from the combined emission spectra, in accordance with the present disclosure. The corresponding photon energies are labeled with solid lines relative to E_{F}.

FIG. 5D is a plot of the isolated thermionic emission spectra from nitrogen-doped diamond films on a p-type doped Si substrate, in accordance with the present disclosure.

FIG. 6 is a plot of the temperature dependence of integrated photon-enhanced emission spectral intensity and thermionic emission intensity, obtained from a nitrogen-doped diamond film on a p-type doped Si substrate, showing results with different excitations energies, in accordance with the present disclosure. Results obtained from an N-doped diamond film on a Mo substrate are also included for comparison. Combined curves of the two models are shown for the three wavelengths, respectively, supporting a contribution from both generation processes.

FIG. 7 is a schematic of the electron distribution and transport for an aspect of an operational I-PETE structure, in accordance with the present disclosure.

FIG. 8 is a schematic of the electron distribution and transport for an aspect of an operational I-PETE structure, in accordance with the present disclosure.

FIG. 9 is a schematic of a proposed diamond-Si structure, showing electrons being excited in the absorbing substrate and contributing to the photon-enhanced emission through the low work function surface.

FIG. 10 is a plot of simulation results of two models on an ideal electron emitter, which has a band gap of 1.12 eV, electron affinity of 0.5 eV, and is under illumination of 400 nm light with a photon flux of 10¹⁵ cm⁻² per second. The thermionic contribution is obtained by calculating the emission current with no photon illumination.

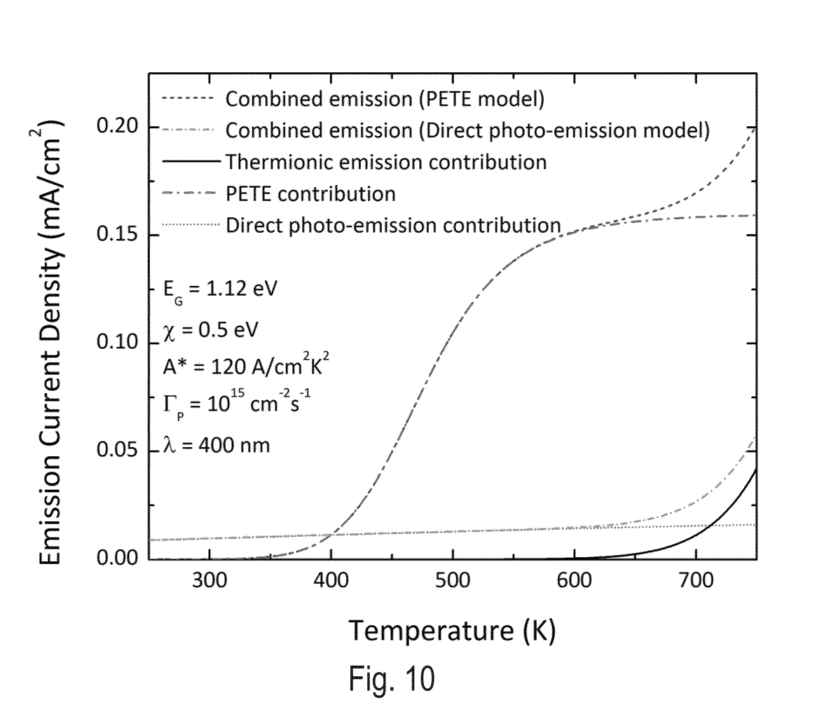

FIG. 11 shows a high resolution electron microscopy image of a diamond/Si interface, in accordance with the present disclosure, showing a nitrogen-incorporated ultra-nanocrystalline diamond layer on the top and single crystal Si substrate on the bottom.

FIG. 12 shows a UV (21.2 eV) photoemission spectra of a nitrogen-doped diamond film on a p-type Si substrate, in accordance with the present disclosure. Data were acquired with a ˜0.02 eV resolution. An effective work function of ˜1.9 eV was observed with was relatively independent of temperature.

### DETAILED DESCRIPTION OF THE INVENTION

Before the present invention is described in further detail, it is to be understood that the invention is not limited to the particular embodiments described. It is also to be understood that the terminology used herein is for the purpose of describing particular embodiments only, and is not intended to be limiting. The scope of the present invention will be limited only by the claims.

As used herein, the singular forms “a”, “an”, and “the” include plural embodiments unless the context clearly dictates otherwise.

Specific structures, devices, and methods relating to solar energy conversion have been disclosed. It should be apparent to those skilled in the art that many additional modifications beside those already described are possible without departing from the inventive concepts. In interpreting this disclosure, all terms should be interpreted in the broadest possible manner consistent with the context. Variations of the term “comprising” should be interpreted as referring to elements, components, or steps in a non-exclusive manner, so the referenced elements, components, or steps may be combined with other elements, components, or steps that are not expressly referenced. Embodiments referenced as “comprising” certain elements are also contemplated as “consisting essentially of” and “consisting of” those elements. If a series of numerical ranges are recited, this disclosure contemplates combinations of the lower and upper bounds of those ranges that are not explicitly recited. For example, if a range between 1 and 10 or between 2 and 9 is recited, this disclosure also contemplates a range between 1 and 9 or between 2 and 10.

This disclosure provides an apparatus. The apparatus can include an emitter electrode, a collector electrode, a vacuum gap, and an electronic circuit.

This disclosure also provides heterostructure suitable for use within the emitter electrode. The heterostructure can include a light absorbing layer and a low work function layer.

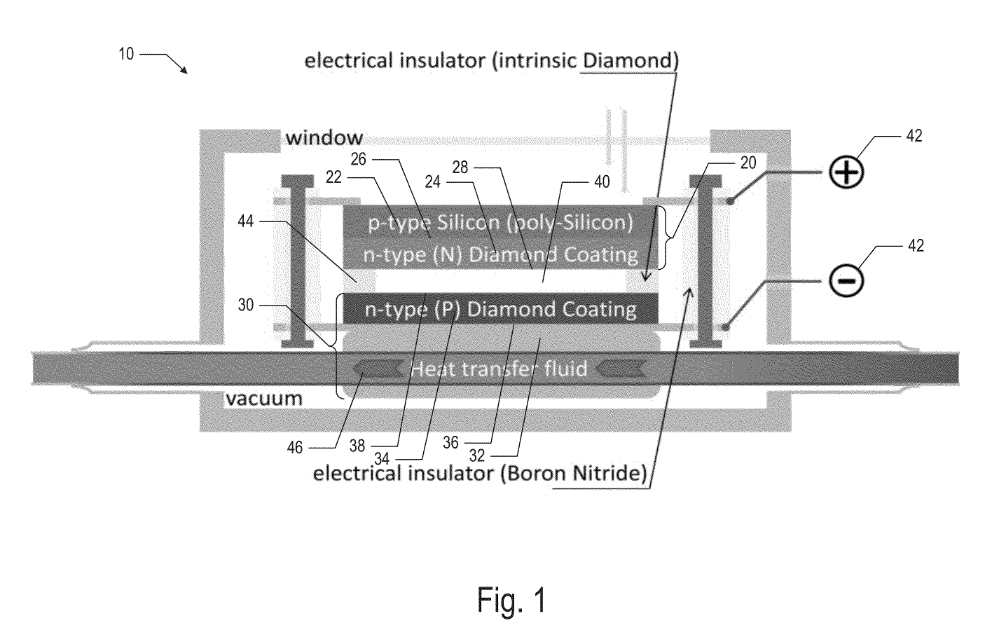

Referring to FIG. 1, an apparatus 10 can comprise an emitter electrode 20 and a collector electrode 30. The emitter electrode 20 can include a first light absorbing layer 22 and a first low work function layer 24. The collector electrode 30 can include a second light absorbing layer 32 and a second low work function layer 34. The apparatus can include a vacuum gap 40 between the first low work function layer 24 and the second low work function layer 34. The emitter electrode 20 can include a first interface 26 between the first light absorbing layer 22 and the first low work function layer 24 and a second interface 28, which can contain a first hydrogen termination surface, between the first low work function layer 24 and the vacuum gap 40. The collector electrode 30 can include a third interface 36 between the second light absorbing layer 32 and the second low work function layer 34 and a fourth interface 38, which can contain a second hydrogen termination surface, between the second low work function layer 34 and the vacuum gap 40. The apparatus can include an electronic circuit 42 that is electronically coupled to the first light absorbing layer 22 and the second light absorbing layer 32. The apparatus can include a heat transfer element that is thermally coupled to the second light absorbing layer 32.

The emitter electrode can include or be coextensive with a heterostructure. The emitter electrode or heterostructure can include a first light absorbing layer and a first low work function layer. The first light absorbing layer and the first low work function layer can be in direct contact with one another.

The first low work function layer can include a material selected from the group consisting of N-doped diamond, P-doped diamond, Si-doped cubic boron nitride, Si-doped AlGaN, Si doped AlN combinations thereof, and the like. In certain aspects, the first low work function layer is N-doped diamond.

The first low work function layer can be disposed at least partially between the first light absorbing layer and the vacuum gap.

The first low work function layer can include an n-type material having an n-type dopant. The first low work function layer can have a concentration gradient of the n-type dopant. The concentration gradient can have a greater concentration of n-type dopant at an interface with the first light absorbing layer when compared to the concentration of n-type dopant at an interface with the vacuum gap. The concentration gradient can have a linear function, a polynomial function, a logarithmic function, combinations thereof, and the like.

The first low work function layer can include a first hydrogen termination surface. The vacuum gap may be in direct contact with at least a portion of the first hydrogen termination surface.

The first low work function layer can have a thickness ranging from about 10 nm to 10 μm, including but not limited to, a thickness ranging from 20 nm to 50 μm, from 50 nm to 10 μm, from 100 nm to 1 μm, from 250 nm to 750 nm, or a thickness ranging from 400 nm to 600 nm.

The first light absorbing layer can include a p-type or n-type semiconductor. In certain aspects, the first light absorbing material includes a p-type semiconductor. The first light absorbing layer can include a material selected from the group consisting of crystalline Si, poly-silicon, amorphous Si, InGaN, InP, GaAs, and the like.

The first light absorbing layer can have an absorption spectrum that at least partially overlaps with a solar spectrum observed from the Earth's surface, from an orbit of the Earth, or a position between the Earth's surface and an orbit of the Earth.

The first light absorbing layer can have a thickness ranging from 10 nm to 100 μm, including but not limited to, a thickness ranging from 20 nm to 50 μm, from 50 nm to 10 μm, from 100 nm to 1 μm, from 250 nm to 750 nm, or a thickness ranging from 400 nm to 600 nm.

Illuminating the emitter electrode or the heterostructure with electromagnetic radiation comprising photons at a flux of between 10¹⁵ cm⁻² per second and 10²¹ cm⁻² per second, including but not limited to, a flux of between 10¹⁶ cm² per second and 10²⁰ cm² per second or a flux of between 10¹⁷ cm⁻² per second and 10¹⁹ cm⁻² per second, and having a wavelength between 300 nm and 1100 nm, including but not limited to, a wavelength between 320 nm and 1000 nm, between 340 nm and 900 nm, between 350 nm and 750 nm, or a wavelength between 400 nm and 450 nm, can induce an emission of electrons from the emitter electrode. The emission of electrons can have effective work function of less than 2.0 eV. The emission of electrons can be greater at certain temperatures. For example, the emission of electrons when the apparatus, emitter electrode, or heterostructure has a temperature of 400° C. can be at least 50% greater than the emission of electrons when the apparatus, emitter electrode, or heterostructure has a temperature of 20° C.

The collector electrode can include a second light absorbing layer and a second low work function layer. The second light absorbing layer can be in direct contact with the second low work function layer.

The second low work function layer can include a material selected from the group consisting of N-doped diamond, P-doped diamond, Si-doped cubic boron nitride, Si-doped AlGaN, Si-doped AlN combinations thereof, and the like. In certain aspects, the second low work function layer can include P-doped diamond.

The second low work function layer can be disposed between the second light absorbing layer and the vacuum gap.

The second low work function layer can have a thickness ranging from 10 nm to 10 μm.

The second light absorbing layer can include a material selected from the group consisting of a metal, a semiconductor, combinations thereof, and the like. The second light absorbing layer can include a material selected from the group consisting of n-type silicon, disordered carbon layers, glassy carbon, metallic layers, composites of metallic or other absorbing materials, combinations thereof, and the like.

The vacuum gap can be disposed between the emitter and the collector. The vacuum gap can be in direct contact with the first low work function layer or the second low work function layer.

The vacuum gap can have a substantially uniform thickness. The vacuum gap can have a thickness ranging from 100 nm to 50 μm. In certain aspects, the vacuum gap can have a thickness ranging from 200 nm to 40 μm, from 500 nm to 25 μm, from 1 μm to 20 μm, or from 3 μm to 10 μm.

In certain aspects, the vacuum gap can have a pressure of less than 1 Torr. In certain aspects, the vacuum gap can have a pressure of less than 10⁻⁸ or less than 10⁻⁹ Torr.

The apparatus can include an electronic circuit. The electronic circuit can be coupled to the emitter electrode and the collector electrode.

The apparatus can also include a spacer or a plurality of spacers. The spacer can be disposed between the emitter electrode and the collector electrode. The spacer can help establish and maintain the vacuum gap. The spacer can help establish and maintain thermal equilibrium between the emitter electrode and the collector electrode.

The spacer can include a spacer material selected from the group consisting of intrinsic diamond, cubic boron nitride, AlN combinations thereof, and the like.

The spacer can include a spacer material having an electrical conductivity of less than 0.1 or 1.0 S/m at 20° C. The spacer can include a spacer material having a thermal conductivity of at least 0.1 or 1.0 Wm⁻¹K⁻¹.

The apparatus can further include a heat transfer element. The heat transfer element can be thermally coupled to the collector electrode. The heat transfer element can be thermally coupled to a heat engine, which a person having ordinary skill in the art will recognize as being any suitable apparatus for converting heat energy into another form, such as a turbine.

This disclosure also provides uses of the apparatuses described herein. The uses include, but are not limited to, use in a solar energy conversion process.

This disclosure also provides solar energy converters. The solar energy converters can include the apparatuses or heterostructures described herein.

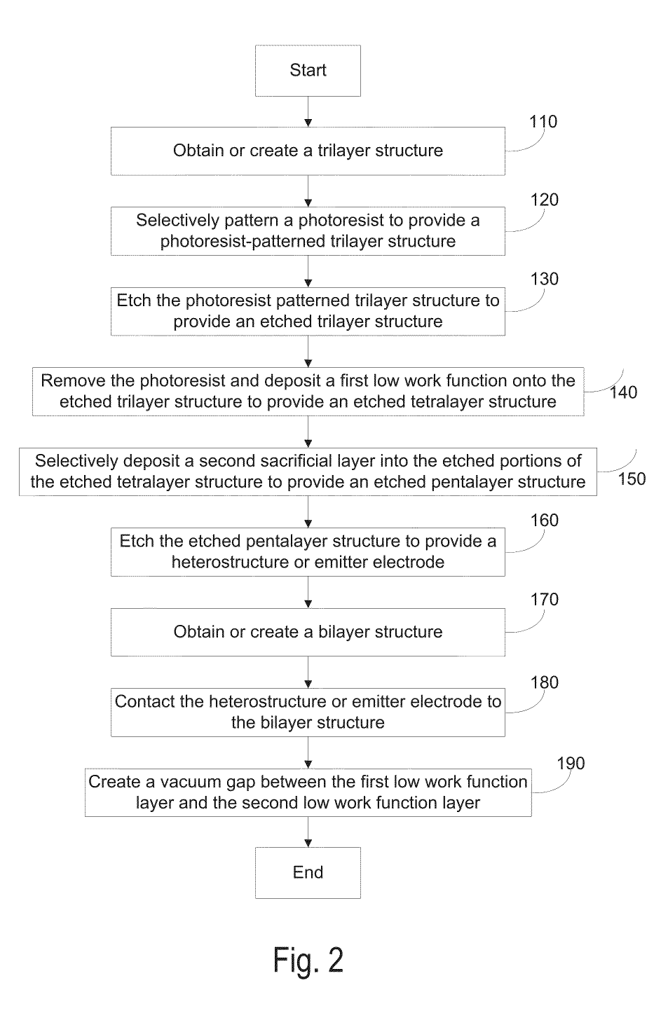

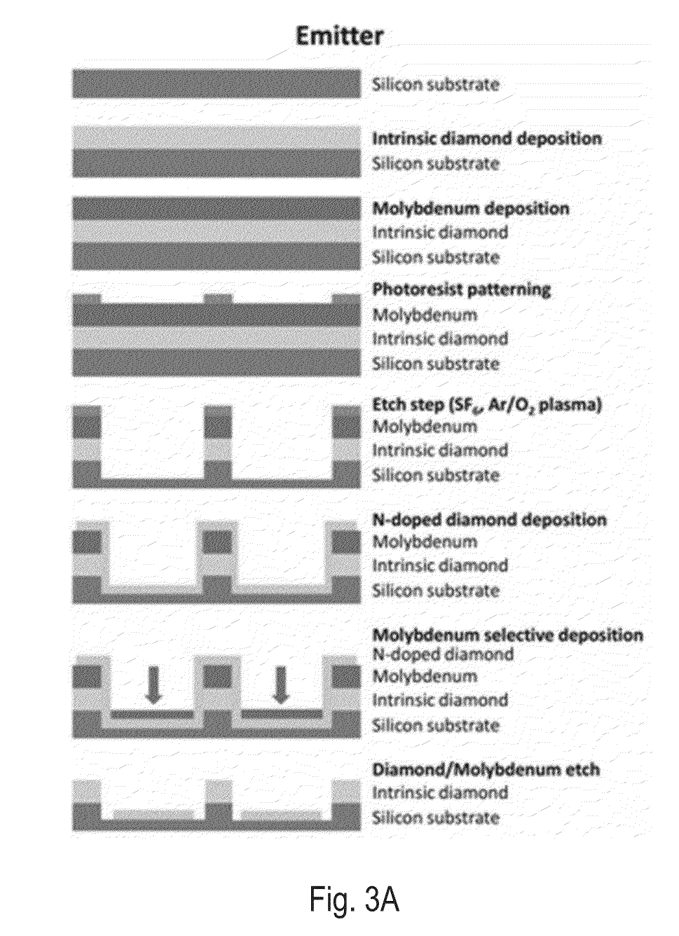

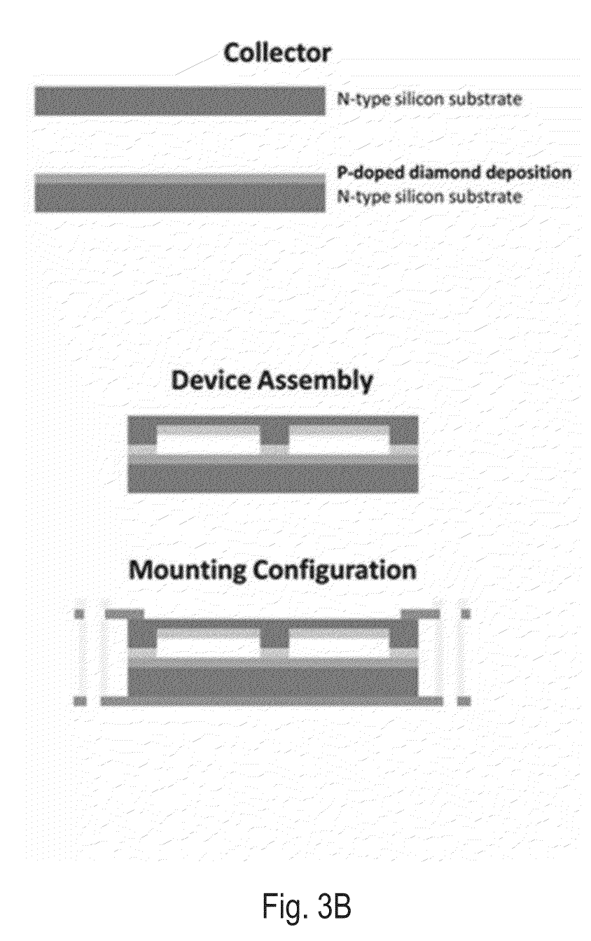

This disclosure also provides methods of making an apparatus or heterostructure described herein. Referring to FIG. 2, a method of making an apparatus can include one or more of the following steps: at process block 110, obtaining or creating a trilayer structure comprising a first light absorbing layer, a spacer layer, and a sacrificial layer; at process block 120, selectively patterning a photoresist onto a surface of the sacrificial layer to provide a photoresist-patterned trilayer structure having covered areas and uncovered areas; at process block 130, etching the photoresist-patterned trilayer structure to remove material beneath uncovered areas to provide an etched trilayer structure having etched portions beneath the uncovered areas, wherein etching removes the sacrificial layer and the spacer layer from the etched portion and optionally removes a portion of the first light absorbing layer from the etched portion; at process block 140, removing the photoresist and depositing a first low work function layer onto the surface of the etched trilayer structure and/or into the etched portion of the etched trilayer structure to provide an etched tetralayer structure; at process block 150, selectively depositing a second sacrificial layer onto a bottom of the etched portions of the etched tetralayer structure to provide an etched pentalayer structure; at process block 160, etching the etched pentalayer structure to remove the second sacrificial layer and at least a portion of the first low work function layer that is not located at the bottom of the etched portions to provide a heterostructure or emitter electrode comprising a first light absorbing layer and a first low worth function, wherein the spacer layer is attached to the heterostructure or emitter electrode; at process block 170, creating a bilayer structure comprising a second light absorbing layer and a second low work function layer; at process block 180, contacting the second low work function layer to the spacer layer; and at process block 190, creating a vacuum gap between the first low work function layer and the second low work function layer. FIGS. 3A and 3B show a schematic representation of one aspect of this method, in accordance with the present disclosure.

A method of making a heterostructure can include one or more of the following steps: obtaining or creating a trilayer structure comprising a first light absorbing layer, a spacer layer, and a sacrificial layer; selectively patterning a photoresist onto a surface of the sacrificial layer to provide a photoresist-patterned trilayer structure having covered areas and uncovered areas; etching the photoresist-patterned trilayer structure to remove material beneath uncovered areas to provide an etched trilayer structure having etched portions beneath the uncovered areas, wherein etching removes the sacrificial layer and the spacer layer from the etched portion and optionally removes a portion of the first light absorbing layer from the etched portion; removing the photoresist and depositing a first low work function layer onto the surface of the etched trilayer structure and/or into the etched portion of the etched trilayer structure to provide an etched tetralayer structure; selectively depositing a second sacrificial layer onto a bottom of the etched portions of the etched tetralayer structure to provide an etched pentalayer structure; and etching the pentalayer structure to remove the second sacrificial layer and at least a portion of the first low work function layer that is not located at a bottom of the etched portions to provide the hetero structure.

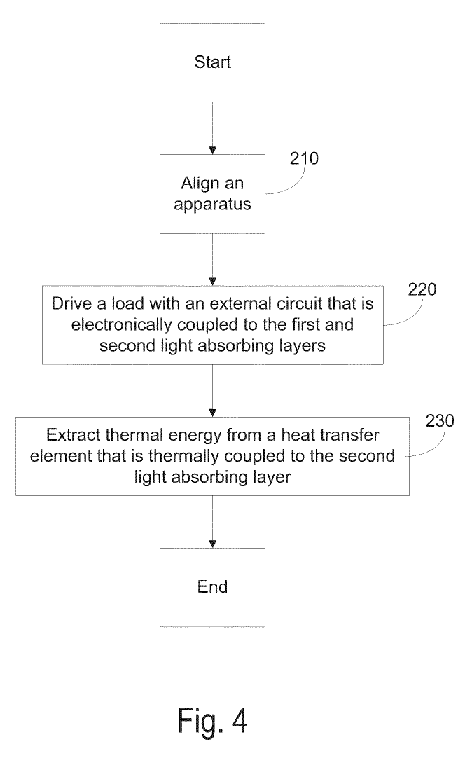

This disclosure also provides methods of converting solar energy. Referring to FIG. 4, a method of converting solar energy can include one or more of the following steps: at process block 210, aligning an isothermal photon-enhanced thermionic emission apparatus so a portion of a solar energy flux that is above the bandgap of a first light absorbing layer of the apparatus interacts with the first light absorbing layer, and a remaining portion of the solar energy flux that is below the bandgap of the first light absorbing layer interacts with a second light absorbing layer of the apparatus; at process block 220, driving a load with an external circuit that is electronically coupled to the first light absorbing layer and the second light absorbing layer; and at process block 230, extracting thermal energy from a heat transfer element that is thermally coupled to the second light absorbing layer.

This disclosure describes an isothermal photon-enhanced thermionic energy (I-PETE) conversion device, the electrodes in which are coated with low work function doped diamond films. Specifically, the electron emitter employs a p-type semiconductor substrate for photon absorption. An n-type substrate configuration is described which may exhibit reduced recombination. The device has a predicted conversion efficiency of greater than 25% for operation between 400° C. and 600° C., when employed in a concentrated solar energy conversion system. At elevated temperatures the topping device can provide increased electrical power output, which is compatible with thermal power plants and solar farms and allows reduction in fossil fuel consumption and increases total plant efficiency.

This disclosure describes a multi-layer emitter and collector structure and a vacuum gap for an isothermal photon-enhanced thermionic emission (I-PETE) topping device.

The emitter structure can employ a p-type Si substrate which provides a band gap that matches to the solar spectrum, and an n-type negative electron affinity diamond film to enable electron emission across the vacuum gap. The above bandgap photons absorbed in the p-type Si can establish a non-equilibrium distribution of electrons in the Si conduction band which can provide an enhanced electron population at the surface of the diamond film. Sub bandgap light will partially pass through the emitter structure and will be absorbed in the collector for transfer to the fluid as heat energy.

The collector layer can employ a doped diamond coated degenerate n-type Si substrate which efficiently accepts negative charge from the photo-excited emitter.

The emitter may also employ an n-type Si substrate. The recombination rate may be significantly reduced in an n-type diamond/n-type Si heterostructure, while the interface barrier could be greater. An optimized substrate will provide the highest net efficiency.

The apparatus can further include undoped diamond post structures that maintain the vacuum gap between the emitter and collector, provide insulating electrical characteristics to sustain the ˜1V potential difference between the surfaces while at the same time providing good thermal conductivity such that the emitter and collector surfaces are at approximately the same temperature. The vacuum gap in this structure allows the conduction bands to align to maximize the electron current. The gap spacing is set to a value that minimizes space charge effects, and for the configurations considered here a gap spacing of less than 10 μm is projected.

The I-PETE device structure can be prepared in a sandwich structure with p-type Si for the emitter substrate and n-type Si for the collector substrate. The electrical isolation can be achieved by exploiting the electrical properties of intrinsic diamond. A thin (0.25-3 μm) layer of intrinsic diamond can be deposited on the silicon substrate followed by deposition of a molybdenum layer (0.2 μm for masking) This metal layer can be patterned using a photoresist (0.2 μm layer thickness) processing step. The nitrogen-doped diamond layer can then be grown onto the structure. Selective deposition of molybdenum in the trenches can again achieved by a masking process. The exposed N-doped diamond can then be etched followed by a final etch of the molybdenum layers. Plasma etching utilizing argon and oxygen has been shown to efficiently etch diamond. For molybdenum either a plasma etch using SF₆ or a wet process can be used. The chemical inertness of diamond allows conventional etching processes for the silicon substrate.

A structure that includes an emitter, collector and vacuum gap where the emitter absorbs light and emits electrons into the vacuum gap based on the PETE and direct photoemission effects, the vacuum gap has thermally conducting structures to maintain the emitter and collector at near the same temperature, and a collector with a low work function to collect the emitted electrons which provide a source of electrical power and absorb heat that would be transferred to a heat reservoir to drive a separate heat engine.

The emitter structure can include a light absorbing layer based on a p-type semiconductor and an n-type, low work function layer such as hydrogen terminated, nitrogen-doped diamond or silicon-doped cubic boron nitride (c-BN) or Si-doped AlGaN or Si-doped AlN to efficiently emit electrons into vacuum. An emitter structure may also include an n-type semiconductor and an n-type, low work function layer as noted above. The interface between the light absorbing layer and the low work function layer should be engineered for efficient electron transfer. It is necessary to avoid the formation of wide band gap interface layers such as SiC. The n-type doping of the diamond layer should vary with the thickness of the layer, with a higher density of doping impurities near the interface and a lower density near the surface.

The vacuum gap can be maintained at a nearly uniform spacing of 3 to 10 μm with electrically insulating and high thermoconductivity materials such as intrinsic diamond or c-BN or AlN.

The collector material can include an absorbing material such as a metal or an n-type degenerately doped semiconductor and a low work function surface layer such as hydrogen terminated, n-type diamond or c-BN, disordered carbon layers, glassy carbon, metallic layers, composites of metallic or other absorbing materials.

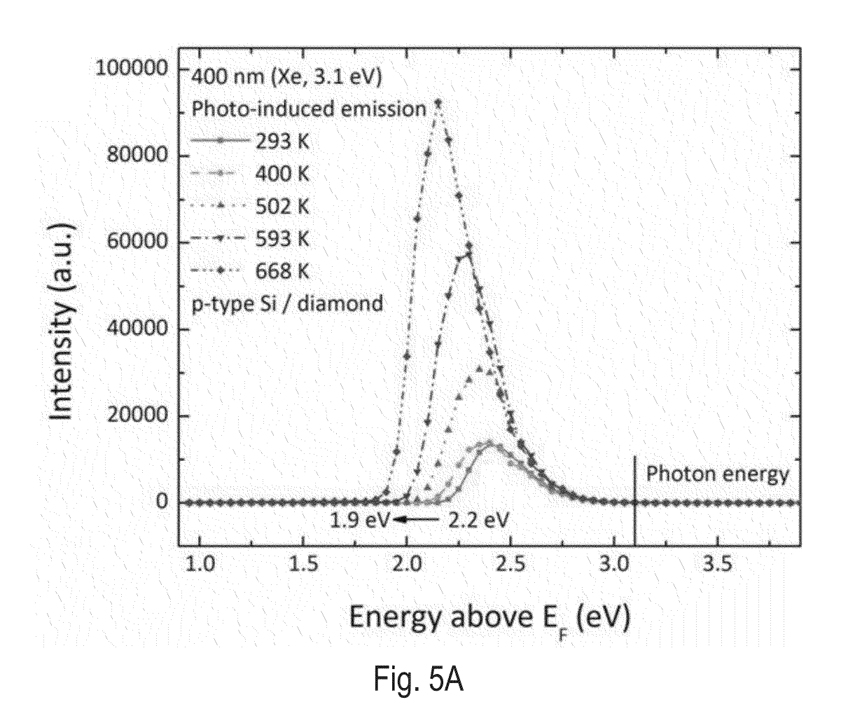

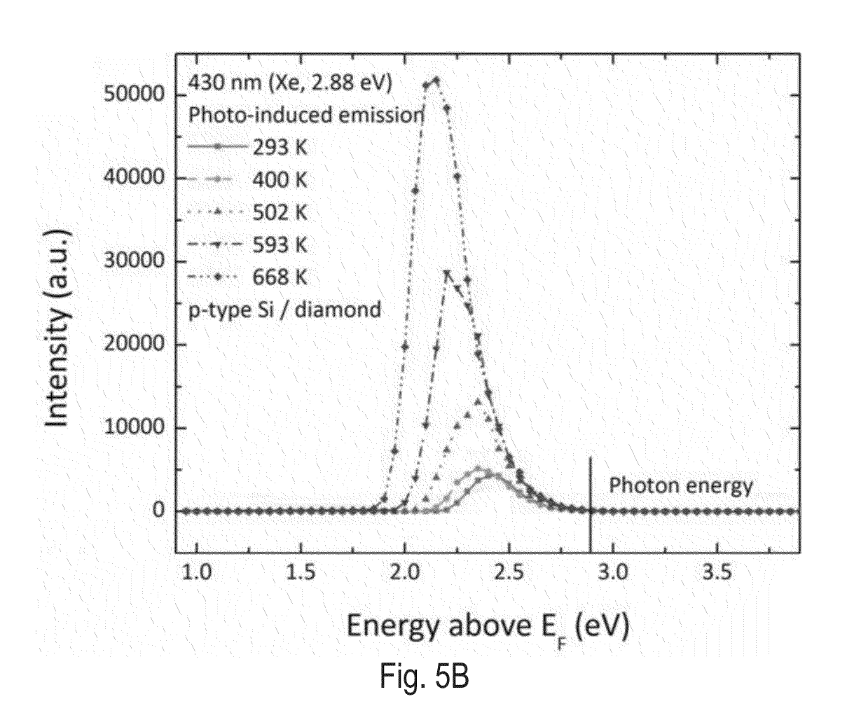

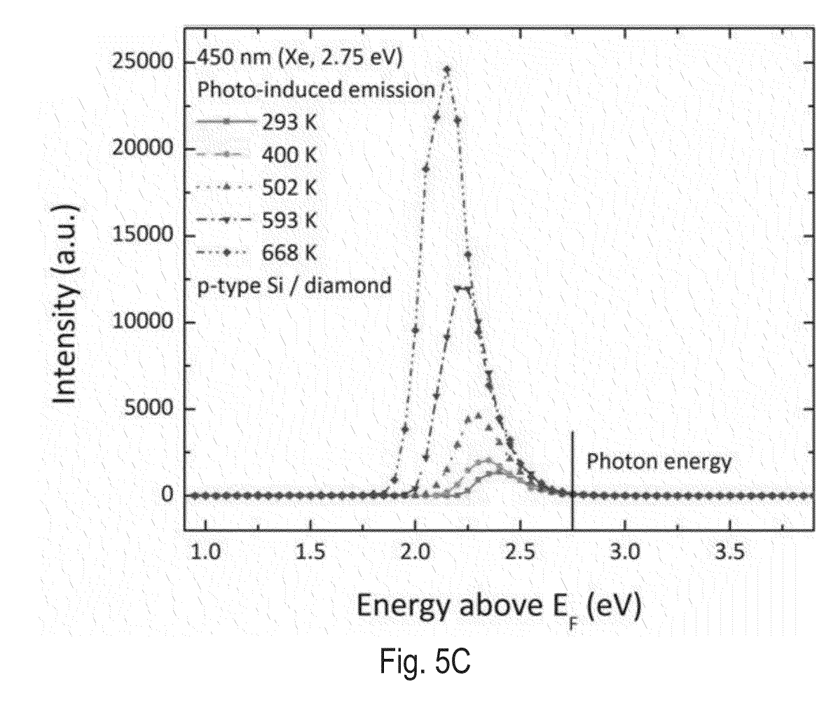

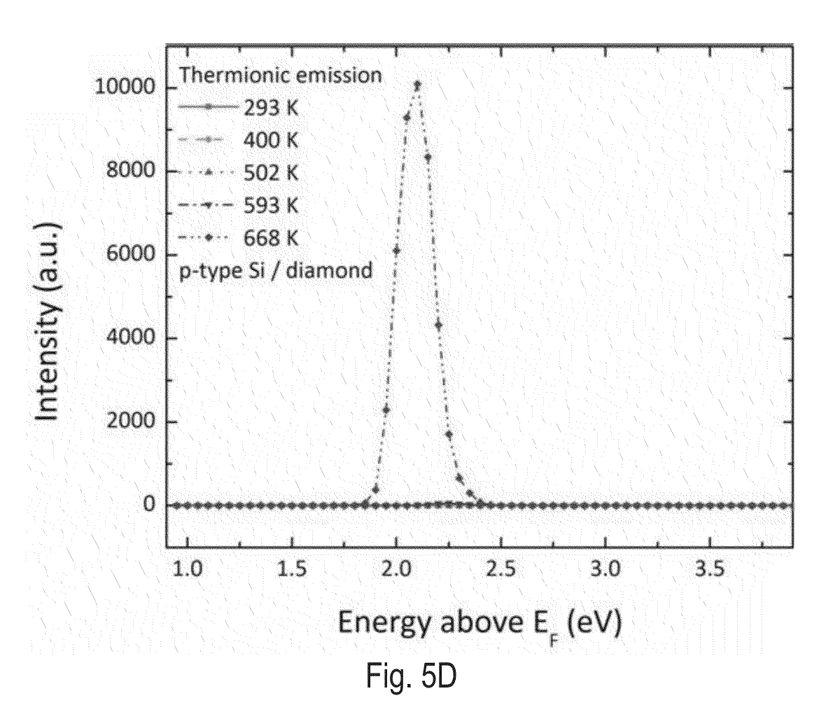

Experiments have demonstrated photon-enhanced electron emission for doped diamond films on p-type Si substrates. The N-doped diamond films were deposited on p-type Si substrates, and the spectrum of the photon-enhanced electron emission was measured as a function of temperature for several wavelengths all below the diamond band gap. The results shown in FIGS. 5A, 5B, 5C, and 5D indicate a nearly 10 fold increase in emission intensity as the temperature is increased. The enhancement is greatest for the lowest energy photons which is attributed to the fact that the direct photoemission process is less significant for the lower energy photons.

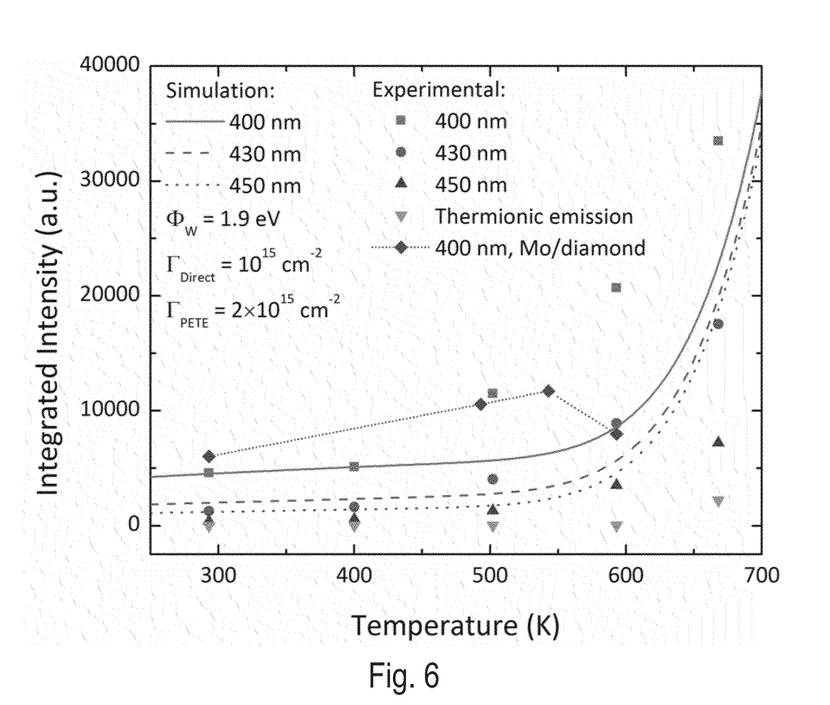

The results are summarized in FIG. 6 where the results were described with a computer simulation that includes the PETE and direct photoemission effects. The enhancement is consistent with the analysis and provides a demonstration of the disclosure.

### Examples

Based on the shortcomings of the prior art, in this disclosure a two-layer configuration is explored that combines a nitrogen-doped (n-type), hydrogen-terminated diamond film and a p-type semiconductor (i.e. silicon) substrate. The advantage of this structure is that the Si substrate is nearly ideal for absorption of the solar spectrum and the p-type character will enable a large increase of the electron quasi-Fermi level. The NEA n-type diamond film provides a low work function surface with potentially reduced recombination due to the lack of mobile holes.

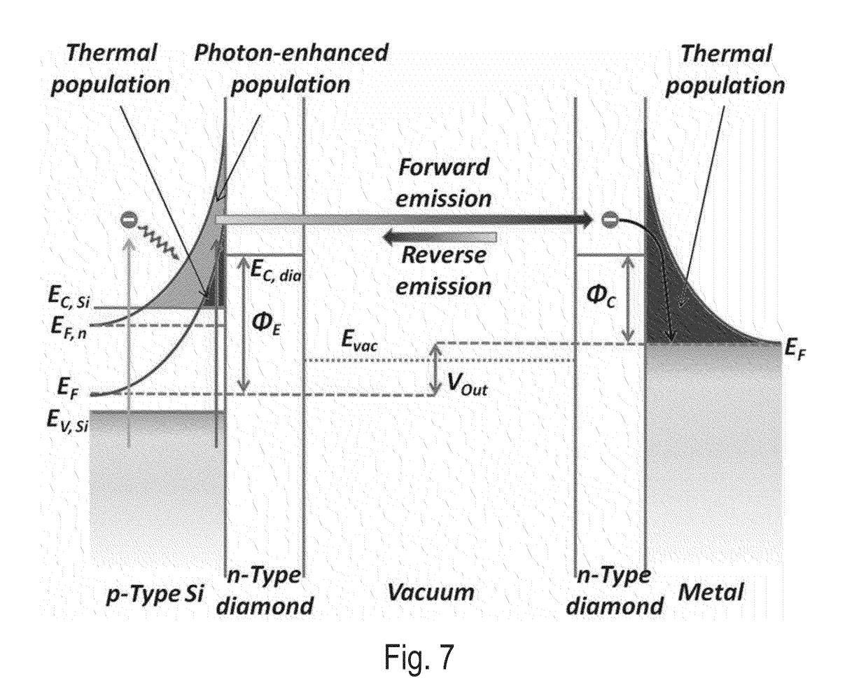

A schematic of the emission mechanism is illustrated in FIGS. 7, 8, and 9: photon-enhanced thermionic electrons are generated in the substrate, transported through the interface towards the diamond surface and contribute to the emission. Due to the wide band gap of diamond (˜5.5 eV at room temperature), it is presumed that the illuminating photons from the front side will be absorbed in the substrate. Alternatively, electrons can be generated directly from valence band states in the Si substrate and injected into the diamond layer without contributing to the enhanced population. This research presents an investigation of the photo-induced electron emission from nitrogen-doped (n-type) diamond films deposited on p-type Si substrates, and particularly its temperature dependence. The results are discussed in terms of the emission mechanisms.

The PETE model from the work by Schwede et al. “Photon-Enhanced Thermionic Emission for Solar Concentrator Systems”, Nat. Mater. 9 (2010): 762-767 is based on a balance between photo-excitation and recombination in a single layer of material, which absorbs photons and emits electrons through the opposite surfaces. In a zero-dimensional simplification, the loss of electrons due to transport between the two surfaces is neglected, which provides a carrier distribution that is essentially identical to our front illumination experimental setup. In the analysis described below in “EXAMPLES—EXPERIMENTAL DETAILS”, the fundamental relationships in both the PETE and the direct photoemission mechanisms are introduced, based on a single-layer film. To apply the two single-layer models to a diamond-Si bi-layer structure, it is assumed that the emission threshold is determined by the interface conduction band barrier. Consequently the electron affinity χ is replaced with the value of this barrier as experimentally measured in the photo-induced emission spectra. Additionally, recombination due to the diamond-Si interface is also ignored, and ideal electron transport properties are assumed. These assumptions may be reasonable since recombination at Si interfaces is typically low and diffusion lengths of electrons in n-type diamond may be expected to be long due to the lack of free holes.

The PETE model is first summarized. It is assumed that all photons with energy above the semiconductor band gap are absorbed and converted into conduction band electrons which follow a thermally stabilized Maxwell-Boltzmann distribution, and the enhanced emission current density is given in a form similar to the Richardson-Dushman relationship for “pure” thermionic electron emission:

$$\begin{matrix}J = {A}^{*} {T}^{2} exp [ - ( {Φ}_{W} - ( {E}_{F , n} - {E}_{F} ) ) / {k}_{B} T ] \\ = e ( {n}_{eq} + dn ) \sqrt{\frac{{k}_{B} T}{2 π {m}_{n}^{*}}} exp [ - χ / {k}_{B} T ] ,\end{matrix} \qquad ( 1 )$$

where A* is the Richardson constant of the emitter, T is the emitter temperature, E_{F,n} is the electron quasi Fermi level, k_{B} is the Boltzmann constant, m: is the electron effective mass, n_{eq} is the equilibrium electron concentrations, dn is the enhanced electron population in the conduction band, and x is the emission barrier height with respect to the CBM. Consequently, the PETE current intensity J can be found by solving dn and substituting into Eq. (1).

It should be noted that recent considerations of the PETE model have focused mostly on p-type substrates. This is due to the fact that the enhancement in PETE is most significant when dn is significantly larger than n_{eq}, as shown in Eq. (1). For an n-type material, as electrons are the majority carriers, the relative enhancement from photon illumination will be considerably smaller compared to a p-type material under the same illumination conditions.

Direct photo-electron generation in a semiconductor, on the other hand, focuses on a non-equilibrium process, where the photo-electrons transport across the interface barrier before thermal relaxation. This calls for a separate analysis. This emission mechanism can be simulated by employing an internal photo-emission model, which describes the quantum yield as a function of the energy of the illuminating photons:

$$Y ( hv ) = \frac{{\int }_{0}^{hv - {E}_{G}} T ( E ) S ( E , hv ) {N}_{C} ( E ) {N}_{v} ( E - hv ) d E}{{\int }_{0}^{hv - {E}_{G}} {N}_{C} ( E ) {N}_{v} ( E - hv ) d E} \\ Y ( hv ) = \frac{{\int }_{0}^{hv - {E}_{G}} T ( E ) S ( E , hv ) {N}_{c} ( E ) {N}_{v} ( E - hv ) d E}{{\int }_{0}^{hv - {E}_{G}} {N}_{c} ( E ) {N}_{v} ( E - hv ) d E} , \qquad ( 2 )$$

where N_{c} and Nᵥ are the conduction band and valence band density of states (DoS) in the absorbing substrate. T(E) and S(E, hv) are the electron emission function and optical absorption function respectively. The energy zero is the CBM. Assuming parabolic DoS for Si and diamond, the direct photo-generation spectrum using the specific diamond properties is obtained through a numerical calculation.

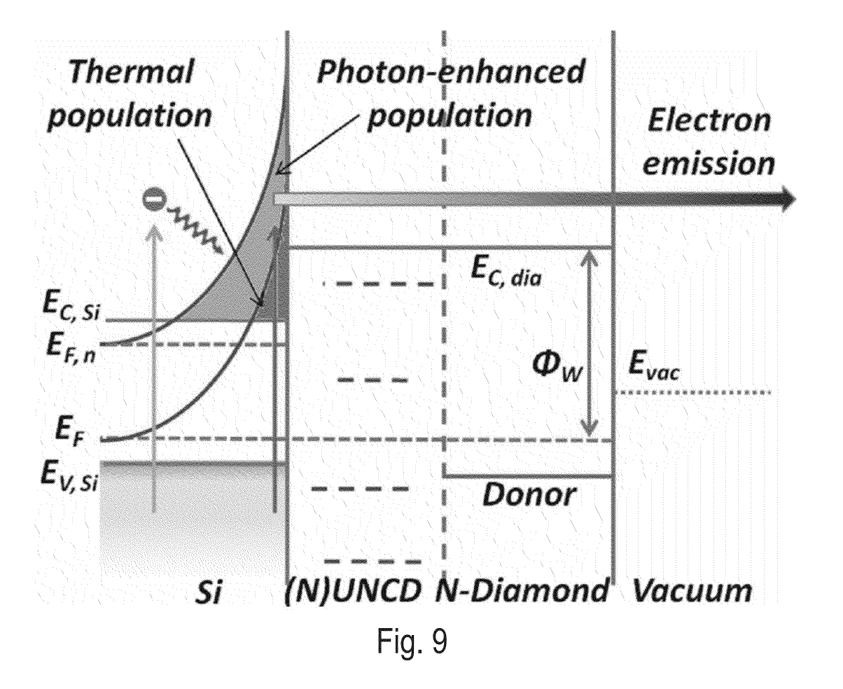

As an example, FIG. 9 shows results of individually applying the two models to an ideal single-layer electron emitter based on p-type Si. The structure includes a constant emission threshold of 0.5 eV above the Si CBM (i.e. χ=0.5 eV), and is illuminated with 400 nm photons at a flux of 10¹⁵ cm⁻² per second. Note that in both models the emission current is approximately proportional to the photon flux in the tested temperature range. Like other studies, the calculation uses the ideal Richardson constant of 120 A/cm²K². The results contain the net current density, and the components contributed by both the “pure” thermionic emission and the photo-induced emission mechanisms, respectively. Comparison between the two models shows different features: the direct photoemission is relatively constant within the tested temperature range, while the PETE induced charge distribution is affected by temperature, and consequently the PETE model results in a more significant temperature dependence. For the specific barrier values employed here, the PETE model shows a much stronger increase of electron emission than the direct photoemission model. Note that under these conditions E_{F,n} is positioned at ˜0.78 eV above the VBM at 300K, and as the temperature is increased to 650K it is reduced to ˜0.14 eV at 650K due to increased recombination. At higher temperatures the thermal excitation of conduction band electrons become more significant than the photo-induced change of E_{F,n}.

In the experimental setup described below in “EXAMPLES—EXPERIMENTAL DETAILS”, the nitrogen-doped diamond films were deposited on boron-doped ([B]˜10¹⁹ cm⁻³) single crystal Si (100) substrates by microwave plasma enhanced chemical vapor deposition (MPCVD). The combined photo-induced and thermionic electron emission spectra were recorded as a function of temperature, using a VSW HA50 hemispherical electron analyzer positioned normal to the sample surface and operated at ˜0.1 eV resolution. The electron emission spectra were referenced to the Fermi level (E_{F}) of the metallic sample holders which was calibrated with a gold foil. A −10V bias was applied to the sample to overcome the analyzer work function and spectra were corrected for the applied bias. The photon source was a focused Oriel 100 W Xe arc lamp with associated band pass filters to provide visible light photons, at an angle of ˜35° to the normal direction.

FIGS. 5A, 5B, and 5C show photo-induced components of the emission spectra collected while the sample was illuminated by selected wavelength photons. When measured at elevated temperatures, the sample also exhibited thermionic emission without photon illumination, which is shown in FIG. 5D. The thermionic emission spectra (TE, “light-off”) were subtracted from the combined emission (“light-on”) to obtain the displayed photo-induced component. Note that the TE component was only significant at the highest temperature, where it was still substantially less than the photo-induced emission component. In contrast to the UV (21.2 eV) photo-emission results, the visible light photo-induced emission spectra exhibited a higher threshold energy which decreased at elevated temperatures. At ˜400° C. where thermionic emission started to be significant, this threshold was found to be approximately the same as the surface work function (1.9 eV). This decrease in low energy cut-off is possibly due to an interface barrier that becomes less significant for transport at elevated temperatures.

FIG. 6 shows the temperature dependence of the integrated spectral intensities for the various illuminating wavelengths. In this measurement series, the sample was illuminated with 400 to 450 nm (3.10 to 2.76 eV) photons at a flux of ˜10¹⁵ cm⁻² per second, and the thermionic emission contribution was subtracted from the combined emission spectrum. At low temperatures, the intensity increases with increasing photon energy, as expected for photoemission. As the sample temperature was increased to ˜400° C., the emission exhibited an intensity increase by a factor of ˜7.3 to 18.4 for the different excitation energies. In contrast, this strong temperature dependence was not observed from diamond films deposited on metal substrates (also shown in FIG. 6). The diamond-metal samples have shown relatively constant photo-induced emission intensity, which is consistent with the conventional Fowler-DuBridge model that only involves direct photoemission. These results are consistent with the model discussed here, since PETE is not expected from a metal substrate.

The modeling results from this N-doped diamond on p-type Si sample are represented by the curves in FIG. 6. The numerical calculations show the sum of emission intensities obtained from the two models, and are based on the temperatures and wavelengths used for the measurements. A photo-emission barrier of 1.9 eV was employed in the simulations. The collection efficiency of the system was varied to fit the results obtained from the different methods. With a photon flux ratio of 1:2 between the direct photoemission model and the PETE model, it was found that the simulation presented a temperature dependence that was similar to the experimental results.

The measurements were repeated for several samples prepared under different conditions. All samples showed similar results with variations in work function and enhancement factors. The samples were also found to show degradation after measurements at high temperature, and the photon-enhancement was substantially reduced in repeated experiments. This could be related to changes of the interface properties and needs further study.

The key question of this study is whether photon-enhanced thermionic emission (PETE) is observed. Most significantly, the diamond on Si showed a substantial increase in intensity as the temperature was increased while for diamond on metals the intensity was approximately constant with temperature. This comparison indicates that the PETE mechanism is consistent with the emission intensity increase for diamond films on Si substrates.

Meanwhile, there is also evidence that suggests the significance of emission mechanisms other than PETE. At lower temperatures (below 200° C.) photo-induced emission can be observed, although the PETE model predicts negligible emission under such conditions. Also, while showing significant temperature dependence, the photo-induced spectra of the diamond-Si samples still show many similarities to the results collected from diamond films deposited on metal substrates. For instance, the spectral intensity shows a dependence on the photon energy, where the maximum electron kinetic energy in the spectrum approximately corresponds to the energy of the illuminating photons. Previously it was concluded that these high energy electrons are from direct excitation of states near E_{F}. For the PETE mechanism, however, the emission spectra are expected to be almost independent of photon energy, since the photo-electrons are thermally stabilized into a Maxwell-Boltzmann distribution regardless of the excitation energy. This supports the direct generation model, as E_{F} in a heavily doped p-type Si wafer is close to the VBM. Therefore, direct generation of photo-electrons should be considered in the observed photo-induced electron emission.

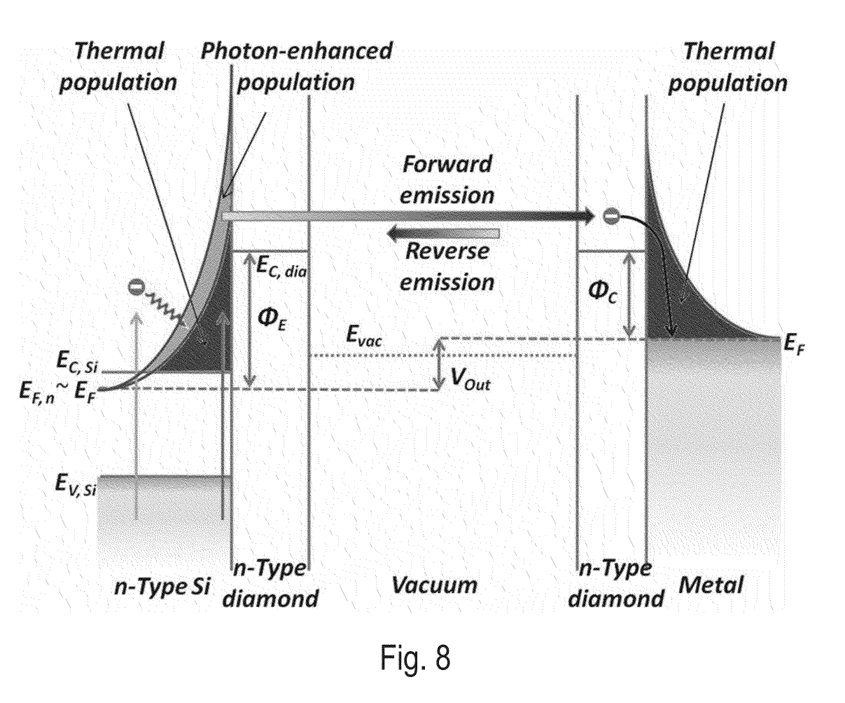

The role of defects in both photo generation and transport has not yet been considered in the models discussed above. Moreover, the actual generation and transport of photo-electrons can be a complex process. In our recent study of N-doped diamond on metal substrates, it was concluded that the photo-electrons may be generated in the substrate or in the nucleation layer which has a higher density of sp² bonds in the grain boundaries. The photon energy dependence shown in FIG. 8 may also be related to smaller optical absorption in the Si substrate for lower energy photons, so that electrons generated deeper in the substrate may contribute less to the observed emission. These results indicate the complexity of the emission process that the two simplified models that were examined cannot independently describe. A more advanced model would be necessary to better assess the specific mechanisms of the more complex double layer structure.

The relative significance of the PETE and direct-generation processes may be related to the properties of the absorbing substrate material. The material will more likely exhibit PETE if forming a quasi-equilibrium population of photo-excited electrons is more favorable than direct injection of the electrons across the barrier. Additionally, an optimal bandgap of the substrate is required to absorb a wide solar spectrum, and it is necessary to limit surface and bulk recombination. It has been assumed that a semiconductor with an indirect bandgap (e.g. Si) will enable PETE-type emission, due to reduced cross-gap recombination and a longer electron relaxation time. These properties, and the NEA of diamond surfaces, lead to the proposed structure in this work. Theoretically, the optimal bandgap for PETE materials has been predicted to be ˜1.4 eV, and candidate substrates including GaAs and InGaN may be appropriate. The properties of these materials related to electron generation and transport may be significant to develop high efficiency PETE devices.

To conclude, a significant increase of photo-induced electron emission at elevated temperatures has been observed from nitrogen-doped diamond films on p-type silicon substrates. The results differ from previously reported features of diamond emitters on metal substrates, where a relatively constant photo-induced emission was observed. The results are consistent with photon-enhanced thermionic emission (PETE), which involves generation of an enhanced electron population and lowering of the emission barrier due to the diamond film. Computer-based modeling is employed to compare different physical mechanisms, and the results appear to indicate a complex generation process. As significant enhancement of electron emission is shown through combined excitation from heat and light, such diamond emitters could potentially be applied in concentrated solar collection systems for solar-thermionic energy conversion. Examination of different substrate candidates to optimize the PETE contribution will be important in the future.

### Examples

### Experimental Details

Prior to growth of the diamond film, the boron-doped Si substrate surface was sonicated in a nano-diamond slurry for 60 min. The sonication process was followed by an acetone rinse and nitrogen gas drying. The nucleation step was then followed by the deposition of a nitrogen-incorporated ultra-nanocrystalline diamond ((N)UNCD) layer and then a polycrystalline nitrogen-doped diamond (N-diamond) layer. The UNCD layer was deposited using 10 sccm argon, 100 sccm nitrogen and 20 sccm methane for 35 min. The N-diamond layer deposition employed hydrogen at 400 sccm, methane at 2 sccm, and nitrogen at 100 sccm for ˜70 min. After deposition, the samples were cooled in a hydrogen plasma (400 sccm hydrogen) for 1 min to obtain H-terminated surfaces.

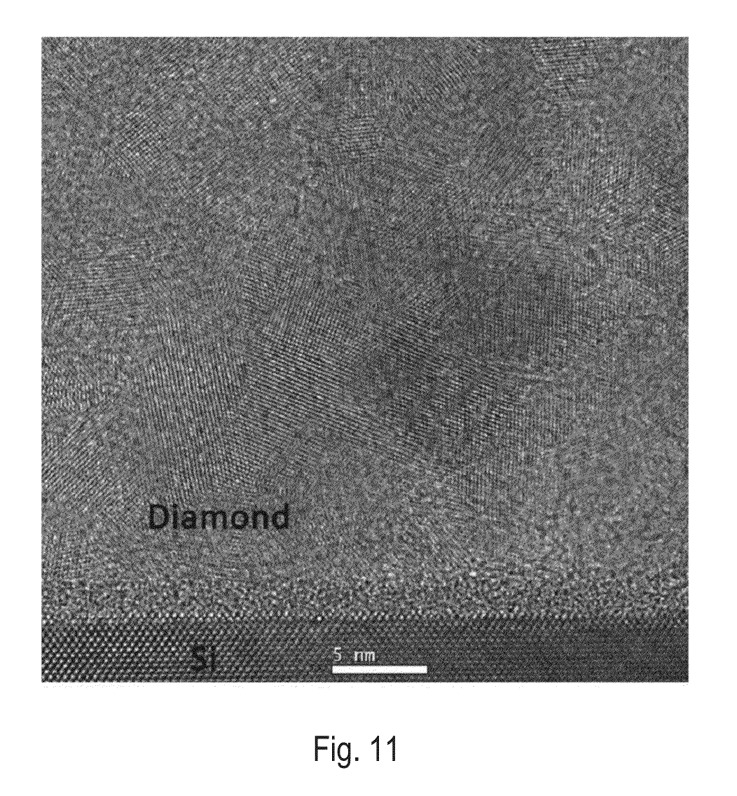

Electron microscopy images of the diamond samples were acquired with a JEOL ARM200F aberration corrected scanning transmission electron microscope (STEM) to examine the diamond/Si interface. The specimen preparation employed a focused ion beam (FIB) lift-out technique using a FEI Nova 200 NanoLab instrument with an Omniprobe tip. Electron microscopy of the sample (FIG. 11) indicates a smooth interface between Si and the (N)UNCD layer. A grain size of less than 10 nm is shown in the (N)UNCD layer. There is a thin layer between the two materials which has a thickness of ˜2 nm. Energy-dispersive X-ray spectroscopy (EDX) measurements indicate that this layer is likely a disordered combination of Si, C and a trace amount of oxygen.

In the electron spectroscopy system, a toroidal tungsten coil beneath the sample provided radiative heating for a temperature range of 20 to 400° C. The sample temperature was monitored with a thermocouple located at the center of the coil, and the sample surface temperature was calibrated with a Mikron M90Q infrared pyrometer throughout the experiments. The vacuum pressure was maintained between 10⁻⁹ to 10⁻⁸ Torr. The band pass filters on the filtered Xe lamp had a FWHM of ˜10 nm. The photon flux was estimated by measuring the radiative power density of the filtered light using a Newport 1916-C optical power meter. During measurements at the same temperature set point, the monitored temperature showed a variance of less than ±2° C., and the light illumination had no observable effect on the measured sample temperature. A Keithley 237 source measuring unit was employed to record the photocurrent from the diamond sample when photon illumination was provided. The measured photocurrent was typically in the range of 0.5 to 5 nA depending on the photon energy, which corresponded to an effective quantum efficiency of ˜10⁻⁵ to 10⁻⁴. Work function of the hemispherical analyzer is ˜4.3 eV as calibrated by a standard Au foil. As this value is higher than the kinetic energy of the emitted electrons, a −10V bias was applied to the sample surface to overcome the analyzer work function. The spectra were shifted by the applied bias. Consequently, the electron energy above E_{F}, KE (sample), is given by the following equation:

KE(sample)=KE(analyzer)−e·V+Φ_{A}, (3)

where KE(analyzer) refers to the electron kinetic energy as measured by the analyzer, V the applied voltage (10V), and Φ_{A} the analyzer work function (4.3 eV).

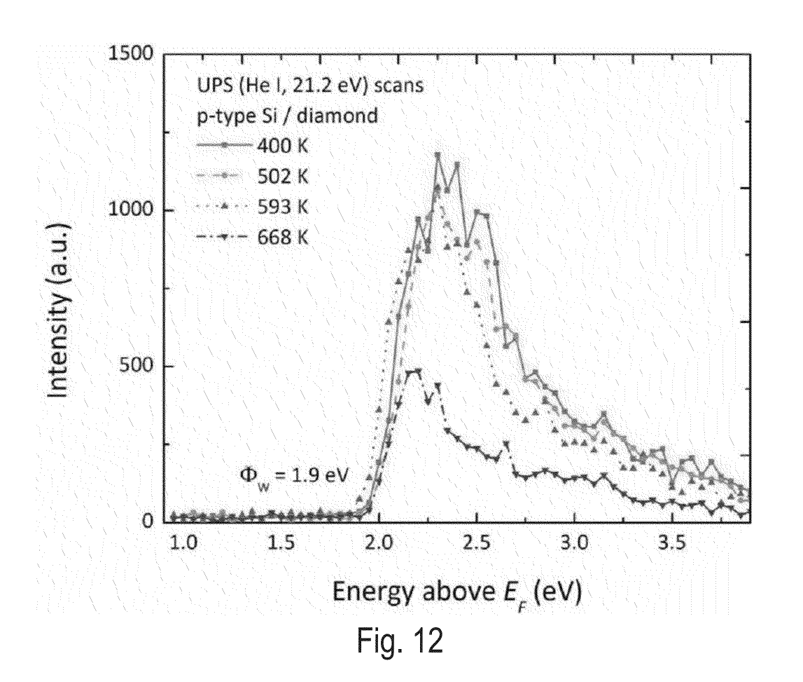

FIG. 12 shows UV photoemission spectra as a function of temperature, collected from a nitrogen-doped diamond film on the p-type Si substrate. The measurements employed a He discharge lamp optimized for generation of He I (21.2 eV) photons, which were delivered to the sample surface through a ˜1.5 mm diameter quartz capillary. As the photon energy is greater than the bandgap of diamond, the photoelectrons are excited from valence band states close to the diamond surface. The electrons in the conduction band lead to the photoemission spectra. Thus, the low energy cut-off of the spectra represents the effective work function Φ_{W} of the N-diamond surface layer. A low value (˜1.9 eV) was observed, which remains approximately constant within the studied temperature regime.

1) Photon-Enhanced Thermionic Emission (PETE) Modeling Approach

For a semiconductor which exhibits PETE, the photons with energy above the band gap will generate electrons in the conduction band and form an enhanced carrier population. This leads to a shift of the quasi-Fermi level in the semiconductor towards the CBM and consequently reduces the effective energy barrier for thermionic emission. As a result, the electron emission intensity may be significantly enhanced with photon illumination. The PETE coefficient K_{PETE} is given as:

$${K}_{PETE} = \sqrt{\frac{{k}_{B} T}{2 π {m}_{n}^{*}}} exp [ - χ / {k}_{B} T ] , \qquad ( 4 )$$

where k_{B} stands for the Boltzmann constant, mₙ*: the electron effective mass, and T the emitter temperature. Only the cross-gap recombination through black-body type radiation is considered here by simplification, which has a coefficient K_{BB} of:

$${K}_{BB} = \frac{2 π}{{h}^{3} {c}^{2} {n}_{eq} {p}_{eq}} {\int }_{{E}_{G}}^{∞} \frac{{( hv )}^{2} d ( hv )}{exp ( hv / {k}_{B} T ) - 1} , \qquad ( 5 )$$

where h stands for the Planck constant, v the photon frequency, c the speed of light, and n_{eq} and p_{eq} the equilibrium electron and hole concentrations. Auger recombination, while neglected here, can become more significant as the electron population increases, and will need to be included for a more complete analysis.

Within the constraints of this model, the equilibrium between generation and recombination leads to the following relationship:

0=(Γ_{P}−K_{PETE}n_{eq})−(K_{PETE}+K_{BB}(n_{eq}+p_{eq}))dn−K_{BB}dn², (6)

where Γ_{P} represents the photon flux, do the enhanced electron population in the conduction band, and χ the emission barrier height with respect to the CBM. To express the analysis in a more familiar form, the photon-enhanced emission current density is given in a form similar to the Richardson-Dushman relationship for “pure” thermionic electron emission:

$$\begin{matrix}J = {A}^{*} {T}^{2} exp [ - ( Φ - ( {E}_{F , n} - {E}_{F} ) ) / {k}_{B} T ] \\ = e ( {n}_{eq} + dn ) \sqrt{\frac{{k}_{B} T}{2 π {m}_{n}^{*}}} exp [ - χ / {k}_{B} T ] .\end{matrix} \qquad ( 7 )$$

2) Direct Photoemission Modeling Approach

Direct photo-electron generation in a semiconductor focuses on a non-equilibrium process, where the photo-electrons transport across the interface barrier before thermal relaxation. This emission mechanism can be simulated by employing an internal photo-emission model, which describes the quantum yield as a function of the energy of the illuminating photons:

$$Y ( hv ) = \frac{{\int }_{0}^{hv - {E}_{G}} T ( E ) S ( E , hv ) {N}_{C} ( E ) {N}_{v} ( E - hv ) d E}{{\int }_{0}^{hv - {E}_{G}} {N}_{C} ( E ) {N}_{v} ( E - hv ) d E} , \qquad ( 8 )$$

where N_{c} and Nᵥ are the conduction band and valence band density of states (DoS) in the absorbing substrate, respectively. The energy zero is referred to the CBM. The emitted electron function, T(E), with kinetic energy E that exceeds the energy barrier χ is given by Fowler's assumption as:

$$T ( E ) = \frac{1}{2} [ 1 - \sqrt{\frac{χ}{E}} ] , E \geq χ ; T ( E ) = 0 , E < χ . \qquad ( 9 )$$

The absorption function S(E, hv) is given in the form of:

$$S ( E , hv ) = \frac{α ( hv ) L ( E )}{1 + α ( hv ) L ( E )} , \qquad ( 10 )$$

which involves α(hv), the frequency dependent optical absorption coefficient of the substrate, and L(E), the electron inelastic mean free path (IMFP). As Si has an indirect band gap of 1.12 eV, its optical properties in the UV and visible wavelength regimes show a significant temperature dependence. For instance, the absorption coefficient (a) of Si as a function of temperature for 400 nm light has been measured experimentally, and an empirical equation in is employed in this work:

$$α ( hv ) = \frac{4 π v}{c} ( - 0.0805 + exp ( - 3.1893 + \frac{7.946}{{3.648}^{2} - {h}^{2} {v}^{2}} ) ) \cdot exp ( \frac{T}{369.9 - exp ( - 12.91 + 5.509 \cdot hv} ) , \qquad ( 11 )$$

where c is the speed of light, T is in the unit of ° C. and hv in eV. The IMFP of low kinetic energy electrons is usually difficult to determine, and thus in this model it is assumed to be a constant ˜100 nm in Si. Assuming parabolic DoS for Si and diamond, and substituting Eq. (8) and (9) into Eq. (7), the direct photo-generation spectrum using the specific diamond properties is obtained through a numerical calculation.

Although the invention has been described in considerable detail with reference to certain embodiments, one skilled in the art will appreciate that the present invention can be practiced by other than the described embodiments, which have been presented for purposes of illustration and not of limitation. Therefore, the scope of the appended claims should not be limited to the description of the embodiments contained herein.

What is claimed is:

1. An apparatus comprising:
an emitter electrode comprising a first light absorbing layer in direct contact with a first low work function layer;
a collector electrode;
a vacuum gap disposed between the emitter and the collector, the vacuum gap in direct contact with the first low work function layer; and
an electronic circuit coupled to the emitter electrode and the collector electrode;
the first low work function layer disposed at least partially between the first light absorbing layer and the vacuum gap.

2. The apparatus of claim 1, wherein the first low work function layer comprises N-doped diamond, P-doped diamond, Si-doped cubic boron nitride, Si-doped AlGaN, Si-doped AlN, or a combination thereof.

3. The apparatus of claim 1, wherein the first low work function layer comprises an n-type material having an n-type dopant.

4. The apparatus of claim 3, wherein the first low work function layer has a concentration gradient of the n-type dopant, wherein the concentration gradient has a greater concentration of the n-type dopant at a first interface between the first light absorbing layer and the first low work function layer compared with a second interface between the first low work function layer and the vacuum gap.

5. The apparatus of claim 1, wherein the first low work function layer comprises a first hydrogen-termination surface, wherein the vacuum gap is in direct contact with at least a portion of the first hydrogen termination surface.

6. The apparatus of claim 1, wherein the first low work function layer has a thickness of 10 nm to 10 μm.

7. The apparatus of claim 1, wherein the first light absorbing layer comprises a p-type or n-type semiconductor.

8. The apparatus of claim 1, wherein the first light absorbing layer has a thickness of 10 nm to 10 μm.

9. The apparatus of claim 1, wherein the collector electrode comprises a second light absorbing layer in direct contact with a second low work function layer, the vacuum gap in direct contact with the second low work function layer.

10. The apparatus of claim 1, wherein the vacuum gap has a substantially uniform thickness of 100 nm to 50 μm.

11. The apparatus of claim 1, wherein the apparatus further comprises a spacer disposed between the emitter electrode and the collector electrode.

12. The apparatus of claim 11, wherein the spacer comprises a spacer material having an electrical conductivity of less than 0.1 S/m at 20° C., a thermal conductivity of at least 1.0 Wm⁻¹K⁻¹, or a combination thereof.

13. The apparatus of claim 1, the apparatus further comprising a heat transfer element thermally coupled to the collector electrode.

14. The apparatus of claim 1, wherein illuminating the emitter electrode with electromagnetic radiation comprising photons at a flux between 10¹⁵ cm⁻² per second and 10²¹ cm⁻² per second and having a wavelength between 300 nm and 1100 nm induces an emission of electrons from the emitter electrode, the emission of electrons having an effective work function of less than 2.0 eV.

15. The apparatus of claim 1, wherein illuminating the emitter electrode with electromagnetic radiation comprising photons at a flux between 10¹⁵ cm⁻² per second and 10²¹ cm⁻² per second and having a wavelength between 300 nm and 1100 nm induces an emission of electrons from the emitter electrode, the emission of electrons when the apparatus has a temperature of 400° C. is at least 50% greater than the emission of electrons when the apparatus has a temperature of 20° C.

16. A solar energy converter comprising the apparatus of claim 1.

17. A heterostructure comprising:
a light absorbing layer; and
a low work function layer in direct contact with the light absorbing layer.

18. The heterostructure of claim 17, wherein the first low work function layer comprises an n-type material having an n-type dopant.

19. The heterostructure of claim 17, wherein the first light absorbing layer comprises a p-type or n-type semiconductor.

20. A method of making an apparatus, the method comprising:
a) obtaining a trilayer structure comprising a first light absorbing layer, a spacer layer, and a sacrificial layer;
b) selectively patterning a photoresist onto a surface of the sacrificial layer to provide a photoresist-patterned trilayer structure covered areas and uncovered areas;
c) etching the photoresist-patterned trilayer structure to remove material beneath uncovered areas to provide an etched trilayer structure having etched portions beneath the uncovered areas, wherein etching removes the sacrificial layer and spacer layer from the etched portion and optionally removes a portion of the first light absorbing layer from the etched portion;
d) removing the photoresist and depositing a first low work function layer onto the surface of the etched trilayer structure and/or into the etched portion of the etched trilayer structure to provide an etched tetralayer structure;
e) selectively depositing a second sacrificial layer onto a bottom of the etched portions of the etched tetralayer structure to provide an etched pentalayer structure;
f) etching the etched pentalayer structure to remove the second sacrificial layer and at least a portion of the first low work function layer that is not located at the bottom of the etched portions to provide a heterostructure or emitter electrode comprising a first light absorbing layer and a first low worth function, wherein the spacer layer is attached to the heterostructure or emitter electrode;
g) obtaining a bilayer structure comprising a second light absorbing layer and a second low work function layer;
h) contacting the second low work function layer to the spacer layer; and
i) creating a vacuum gap between the first low work function layer and the second low work function layer.
